(19) United States
(12) Patent Application Publication
(10) Pub. No.: US 2024/0348945 A1
(43) Pub. Date: Oct. 17, 2024

(54) SOLID-STATE IMAGING DEVICE

(71) Applicant: SONY SEMICONDUCTOR SOLUTIONS CORPORATION, KANAGAWA (JP)

(72) Inventor: YUKIHITO IIDA, KANAGAWA (JP)

(21) Appl. No.: 18/294,644

(22) PCT Filed: Mar. 9, 2022
(86) PCT No.: PCT/JP2022/010413

§ 371 Date: Feb. 2, 2024

(30) Foreign Application Priority Data
Sep. 6, 2021 (JP) 2021-145053

(51) Int. Cl. H04N 25/77; H01L 27/146; H04N 25/766

(52) U.S. Cl. CPC H04N 25/77; H01L 27/14609; H01L 27/14636; H04N 25/766

(57) ABSTRACT

A solid-state imaging device includes: a photoelectric conversion element that generates electric charge from light through photoelectric conversion; a transfer transistor that is coupled to the photoelectric conversion element; a pixel in which a plurality of the photoelectric conversion elements and a plurality of the transfer transistors are arrayed; a floating diffusion that is commonly coupled, with the respective transfer transistors interposed in between, to the plurality of photoelectric conversion elements of the pixel, and transfers the electric charge; a pixel circuit that is coupled to the floating diffusion and converts the electric charge into electric signals; a switch that has a first main electrode coupled to the floating diffusion and has a first control electrode to which a first control signal is inputted, the first control signal controlling a conductive state and a non-conductive state in accordance with an electric charge amount of the floating diffusion; and a variable capacitor that has a first electrode coupled to a second main electrode of the switch and has a second electrode to which a second control signal is inputted, the second control signal controlling a capacitance value in accordance with the electric charge amount.

### TECHNICAL FIELD

The present disclosure relates to a solid-state imaging device.

### BACKGROUND ART

PTL 1 discloses a solid-state imaging device. A pixel of the solid-state imaging device includes a photodiode, a transfer transistor, a floating diffusion, a source follower transistor, and a variable capacitance unit.

The photodiode stores electric charge converted from light. The electric charge stored in the photodiode is transferred from the transfer transistor to the source follower transistor via the floating diffusion. In the source follower transistor, the electric charge is converted into a voltage signal with a gain corresponding to an amount of the transferred electric charge. A capacitance conversion unit is coupled to the floating diffusion. A capacitance change signal is inputted into the capacitance conversion unit.

In the solid-state imaging device configured in this manner, the capacitance change signal changes a capacitance value of the capacitance conversion unit. As a result, the capacitance value to be added to the floating diffusion is changed, making it possible to switch a conversion gain.

### CITATION LIST

### Patent Literature

PTL 1: Japanese Unexamined Patent Application Publication No. 2016-219857

### SUMMARY OF THE INVENTION

In such a solid-state imaging device, a change in a capacitance value of a capacitance conversion unit is limited to two values. In addition, it is not possible to obtain a sufficient variable amount of the capacitance value because a parasitic capacitor is added to a floating diffusion.

Furthermore, in a case where the capacitance conversion unit includes a MOS (Metal Oxide Semiconductor) type capacitor, the capacitance value of the capacitance conversion unit varies in accordance with fluctuations in electric charge (potential) to be transferred to the floating diffusion. Therefore, it is not possible to maintain linearity of changing efficiency.

Hence, it is desirable to develop a solid-state imaging device that makes it possible to change to a large number of capacitance values, such as three values or more, and to obtain the sufficient variable amount of the capacitance value. Furthermore, it is desirable to develop a solid-state imaging device that makes it possible to maintain the linearity of conversion efficiency.

A solid-state imaging device according to one embodiment of the present disclosure includes: a photoelectric conversion element that generates electric charge from light through photoelectric conversion; a transfer transistor that is coupled to the photoelectric conversion element; a pixel in which a plurality of the photoelectric conversion elements and a plurality of the transfer transistors are arrayed; a floating diffusion that is commonly coupled, with the respective transfer transistors interposed in between, to the plurality of photoelectric conversion elements of the pixel, and transfers the electric charge; a pixel circuit that is coupled to the floating diffusion and converts the electric charge into electric signals; a switch that has a first main electrode coupled to the floating diffusion and has a first control electrode to which a first control signal is inputted, the first control signal controlling a conductive state and a non-conductive state in accordance with an electric charge amount of the floating diffusion; and a variable capacitor that has a first electrode coupled to a second main electrode of the switch and has a second electrode to which a second control signal is inputted, the second control signal controlling a capacitance value in accordance with the electric charge amount.

Here, the switch and the variable capacitor configure. a variable capacitance circuit. The variable capacitor includes a p-channel conductivity type insulated gate field effect transistor.

### BRIEF DESCRIPTION OF DRAWING

FIG. 1 is a circuit diagram including a pixel, a pixel circuit, and variable capacitance circuit of a solid-state imaging device according to a first embodiment of the present disclosure.

FIG. 2 is a schematic vertical cross-sectional configuration diagram of the solid-state imaging device including the pixel, the pixel circuit, and the variable capacitance circuit illustrated in FIG. 1.

FIG. 3 is a plane configuration diagram of the pixel illustrated in FIG. 2.

FIG. 4 is a plane configuration diagram of the pixel circuit and the variable capacitance circuit illustrated in FIG. 2.

FIG. 5 is a schematic enlarged plane configuration diagram of a variable capacitor that configures the variable capacitance circuit illustrated in FIG. 4.

FIG. 6 is a time chart describing a readout operation of the solid-state imaging device illustrated in FIG. 1.

FIG. 7A is a table describing conversion efficiency corresponding to the readout operation of the solid-state imaging device illustrated in FIG. 1.

FIG. 7B is a circuit diagram that simplifies FIG. 1 describing a correction operation of the conversion efficiency in the readout operation of the solid-state imaging device illustrated in FIG. 1.

FIG. 8 is a table describing conversion efficiency corresponding to a readout operation of a solid-state imaging device according to a first modification example of the first embodiment.

FIG. 9 is a circuit diagram corresponding to FIG. 1, including a pixel, a pixel circuit, and a variable capacitance circuit of a solid-state imaging device according to a second embodiment of the present disclosure.

FIG. 10 is a circuit diagram corresponding to FIG. 7B, including a variable capacitance circuit of a solid-state imaging device according to a third embodiment of the present disclosure.

FIG. 11 is a block circuit diagram illustrating an array configuration of pixels and wiring lines of a solid-state imaging device according to a fourth embodiment of the present disclosure.

FIG. 12 is a block circuit diagram corresponding to FIG. 11, illustrating an array configuration of pixels and wiring lines of a solid-state imaging device according to a fifth embodiment of the present disclosure.

FIG. 13 is a block diagram depicting an example of schematic configuration of a vehicle control system.

FIG. 14 is a diagram of assistance in explaining an example of installation positions of an outside-vehicle information detecting section and an imaging section.

### MODES FOR CARRYING OUT THE INVENTION

In the following, some embodiments of the present disclosure will be described in detail with reference to the drawings. It is to be noted that the description will be given in the following order.

### 1. First Embodiment

In a first embodiment, an example is described in which the present technology is applied to a solid-state imaging device. In the first embodiment, a detailed description is given of a circuit configuration, a vertical cross-sectional configuration, a plane configuration, and a readout operation of the solid-state imaging device. In addition, for a solid-state imaging device according to a first modification example of the first embodiment, a description is given of a variable capacitance circuit that is able to set a large number of capacitance values. Furthermore, for a solid-state imaging device according to a second modification example of the first embodiment, a description is given of an example in which a configuration of a variable capacitor of the variable capacitance circuit is changed.

### 2. Second Embodiment

In a second embodiment, a description is given of a first example in which a configuration of a variable capacitance circuit is changed in the solid-state imaging device according to the first embodiment.

### 3. Third Embodiment

In a third embodiment, a description is given of a second example in which the configuration of the variable capacitance circuit is changed in the solid-state imaging device according to the first embodiment.

### 4. Fourth Embodiment

In a fourth embodiment, a description is given of a first example in which a control signal wiring line for inputting a control signal to the variable capacitance circuit is shared in the solid-state imaging device according to the first embodiment.

### 5. Fifth Embodiment

In a fifth embodiment, a description is given of a second example in which the control signal wiring line for inputting a control signal to the variable capacitance circuit is shared in the solid-state imaging device according to the first embodiment.

### 6. Application Example to Mobile Body

A description is given of an example in which the present technology is applied to a vehicle control system that is an example of a mobile body control system.

### 7. Other Embodiments

### 1. First Embodiment

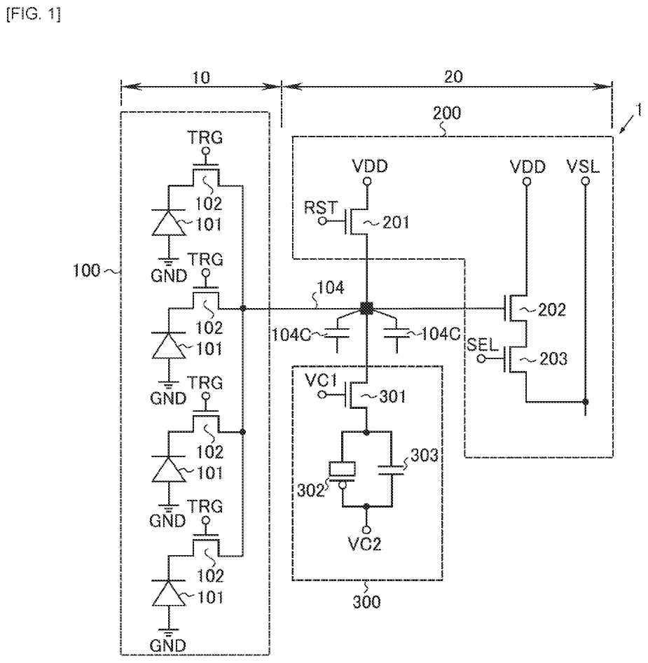

With reference to FIG. 1 to FIG. 8, a description will be given of a solid-state imaging device 1 according to the first embodiment of the present disclosure.

Here, in the figures, an arrow X direction illustrated appropriately represents one plane direction of the solid-state imaging device 1 placed on a plane, for convenience. An arrow Y direction represents another one plane direction orthogonal to the arrow X direction. In addition, an arrow Z direction is an upward direction orthogonal to the arrow X direction and the arrow Y direction. That is, the arrow X direction, the arrow Y direction, and the arrow Z direction exactly correspond to an X axis direction, a Y axis direction, and a Z axis direction, respectively, of a three-dimensional coordinate system.

It is to be noted that these directions are each illustrated to help understand the description, and not intended to limit directions of the present technology.

### [Configuration of Solid-State Imaging Device 1]

### (1) Circuit Configuration of Solid-State Imaging Device 1 and Pixel Circuit 200

FIG. 1 illustrates an example of a circuit configuration of a pixel 100 and a pixel circuit 200 that construct the solid-state imaging device 1.

One pixel 100 includes a plurality of photoelectric conversion elements (Photodiodes) 101 and a plurality of transfer transistors 102. Here, by way of example, is formed, the one pixel 100 including the four photoelectric conversion elements 101 and the four transfer transistors 102 each of which is disposed corresponding to each of these four photoelectric conversion elements 101.

An anode terminal of the photoelectric conversion element 101 is coupled to a reference potential GND, for example. A cathode terminal of the photoelectric conversion element 101 is coupled to one terminal of the transfer transistor 102. That is, the one photoelectric conversion element 101 and the one transfer transistor 102 configure a series circuit. Stated differently, each of the transfer transistors 102 is coupled to each of the plurality of photoelectric conversion elements 101.

The photoelectric conversion element 101 generates electric charge from light entering from outside of the solid-state imaging device 1, through photoelectric conversion.

Another terminal of the transfer transistor 102 is commonly coupled to the pixel circuit 200 with a floating diffusion (Floating Diffusion) 104 interposed in between. Here, the four transfer transistors 102 are commonly coupled to the one floating diffusion 104. Stated differently, the one floating diffusion 104 commonly coupled is disposed in the one pixel 100. In addition, a horizontal scanning signal TRG is inputted to a control terminal of each of the plurality of transfer transistors 102.

The transfer transistors 102 transfer the electric charge generated by the photoelectric conversion elements 101 to the pixel circuit 200 through the floating diffusion 104.

The pixel circuit 200 includes a reset transistor 201, an amplification transistor 202, and a selection transistor 203. Here, the one pixel circuit 200 is disposed for every four photoelectric conversion elements 101 and four transfer transistors 102.

The other terminal of the transfer transistor 102 is coupled to one terminal of the reset transistor 201 and a control terminal of the amplification transistor 202.

Another terminal of the reset transistor 201 is coupled to a power supply potential VDD. In addition, a reset signal RST is inputted to a control terminal of the reset transistor 201.

One terminal of the amplification transistor 202 is coupled to one terminal of the selection transistor 203. Another terminal of the amplification transistor 202 is coupled to the power supply potential VDD. In the amplification transistor 202, an electric signal (voltage signal) is generated with a gain corresponding to an electric charge amount of the electric charges to be transferred through the floating diffusion 104.

Another terminal of the selection transistor 203 is coupled to a vertical signal line VSL. A selection signal SEL is inputted to a control terminal of the selection transistor 203.

### (2) Circuit Configuration of Variable Capacitance Circuit 300

A variable capacitance circuit 300 is electrically coupled to the floating diffusion 104 in parallel that couples the pixel 100 and the pixel circuit 200. Here, the one variable capacitance circuit 300 is disposed in the one floating diffusion 104.

The variable capacitance circuit 300 includes a switch 301 and a variable capacitor 302 as main components. Furthermore, the variable capacitance circuit 300 also includes a capacitor 303.

The switch 301 includes an insulated gate field effect transistor (IGFET: Insulated Gate Field Effect Transistor) of the first conductivity type. The first conductivity type is here “n-type”. In addition, IGFET includes a metallic body-oxide film-semiconductor type IGFET (MOSFET: Metal Oxide Semiconductor Field Effect Transistor) and a metallic body-insulator-semiconductor type IGFET (MISFET: Metal Insulator Semiconductor Field Effect Transistor).

One terminal of the switch 301 (first main electrode) is electrically coupled in parallel to the floating diffusion 104. Another terminal (second main electrode) of the switch 301 is coupled to one electrode (first electrode) of the variable capacitor 302. A first control signal VC1 is inputted to a control terminal (first control electrode) of the switch 301. The first control signal VC1 is a signal that controls a conductive (ON) state and non-conductive (OFF) state of the switch 301 in accordance with the electric charge amount of the electric charges to be transferred to the floating diffusion 104.

A second control signal VC2 is inputted to another electrode (second electrode) of the variable capacitor 302. Similarly to the first control signal VC1, the second control signal VC2 is a signal that controls a capacitance value of the variable capacitor 302 in accordance with the electric charge amount of the electric charges to be transferred to the floating diffusion 104.

The variable capacitor 302 includes a metallic body-insulator-semiconductor (MIS: Metal Insulator Semiconductor) type variable capacitance diode (Variable Capacitance Diode) structure. The MIS type variable capacitance diode structure includes a metallic body-oxide film-semiconductor (MOS: Metal Oxide Semiconductor) type variable capacitance diode structure. That is, in the variable capacitor 302, one electrode is a metallic body and another electrode is a semiconductor. Extension of a depleted layer in a semiconductor varies depending on a difference in voltages applied between the electrodes, and the capacitance value of the variable capacitor 302 varies. In general, when a voltage difference is “small”, the capacitance value is “small”, and when the voltage difference is “large”, the capacitance value is “large”.

Furthermore, the variable capacitor 302 is configured utilizing a second conductivity type IGFET in the first embodiment. Here, the second conductivity type is a “p-type” that is an opposite conductivity type to the first conductivity type. A specific structure of the variable capacitor 302 is described in detail below.

The capacitor 303 is electrically coupled in parallel between the one electrode and the other electrode of the variable capacitor 302. The capacitor 303 is configured utilizing a parasitic capacitor. A specific configuration of the capacitor 303 is described in detail below.

It is to be noted that a parasitic capacitor 104C is added to the floating diffusion 104.

### (3) Specific Configuration of Pixel 100 and Pixel Circuit 200

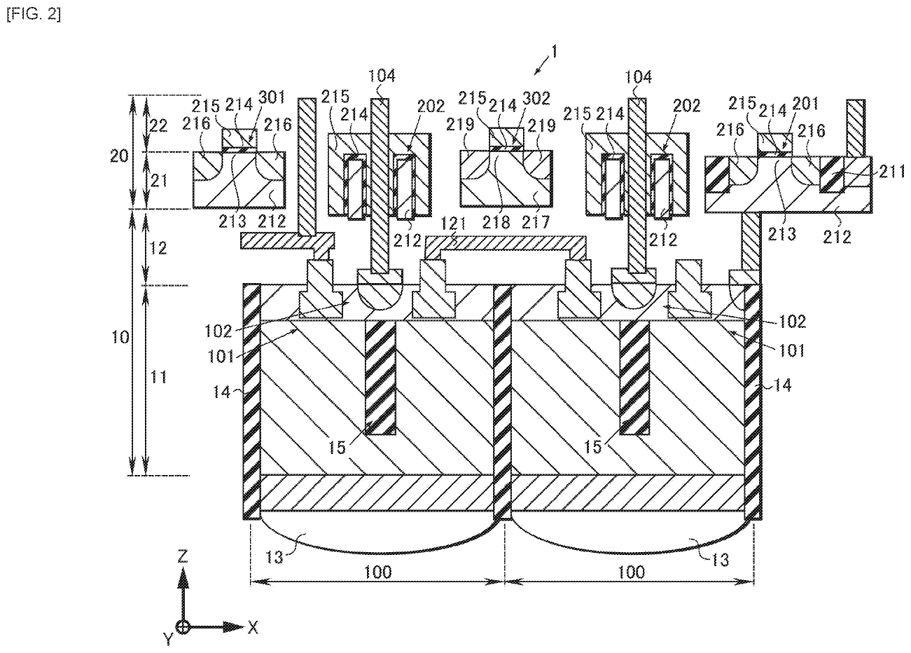

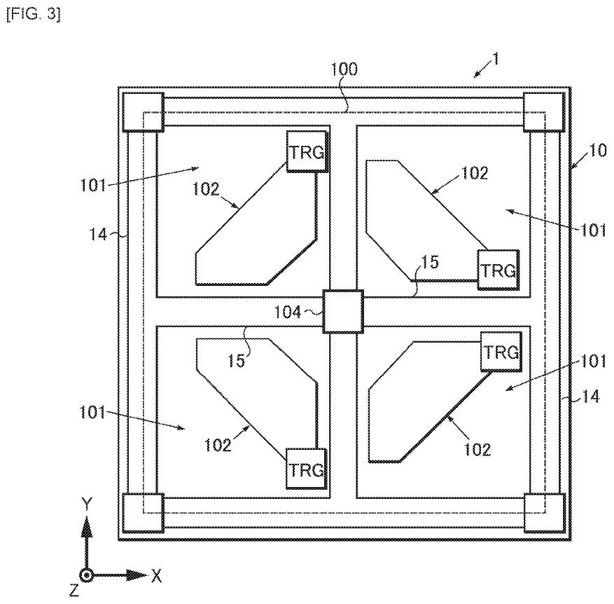

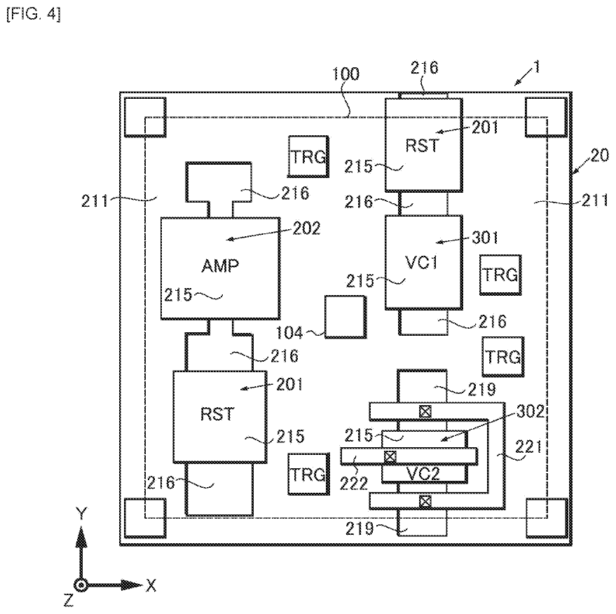

FIG. 2 schematically illustrates an example of a vertical cross-section configuration of the solid-state imaging device 1. FIG. 3 illustrates an example of plane configuration of the pixel 100 including the photoelectric conversion elements 101 and the transfer transistors 102. In addition, FIG. 4 illustrates an example of an example of a plane configuration of the pixel circuit 200 and the variable capacitance circuit 300.

Here, the solid-state imaging device 1 is configured as a back-illuminated image sensor. As illustrated in FIG. 2, when viewed from the arrow Y direction (hereinafter simply referred to as “in a side view”), the solid-state imaging device 1 includes a first base body 10 and a second base body 20 that are stacked in sequence. That is, the second base body 20 is stacked on the first base body 10, and the second base body 20 is bonded to the first base body 10.

The first base body 10 includes a first semiconductor layer 11 and a first wiring line layer 12 disposed on side of the second base body 20 of the first semiconductor layer 11. The first semiconductor layer 11 is formed of, for example, monocrystalline silicon (Si).

The first semiconductor layer 11 includes the pixel 100. Although a detailed structure of the photoelectric conversion element 101 of the pixel 100 is omitted, the photoelectric conversion element 101 includes an n-type semiconductor region and a p-type semiconductor region, and is configured by a p-n junction of both the n-type semiconductor region and the p-type semiconductor region.

On light-entering side of the photoelectric conversion element 101, a light receiving lens 13 is disposed with an unillustrated charge fixing film and insulating film interposed in between. The light receiving lens 13 is disposed on every pixel 100 or on every photoelectric conversion element 101. The light receiving lens 13 is able to condense light that enters the photoelectric conversion element 101. Here, the light-entering side is opposite side to side of the second base body 20 of the first semiconductor layer 11, in a side view.

Although a detailed structure of the transfer transistor 102 of the pixel 100 is similarly omitted, the transfer transistor 102 is configured on a surface portion of the first semiconductor layer 11 on the side of the second base body 20. The transfer transistor 102 includes the first conductivity type IGFET, that is, an n-channel conductivity type IGFET. The transfer transistor 102 includes: a pair of the main electrodes (terminals) that are a source region and a drain region with no reference numeral; a channel forming region; a gate insulating film; and a gate electrode (control electrode). The pair of the main electrodes is the n-type semiconductor regions.

As illustrated in FIG. 2 and FIG. 3, a pixel isolation region 14 is disposed between the pixel 100 and another pixel 100 that is adjacent to the pixel 100 in the arrow X direction and the arrow Y direction. In addition, an element isolation region 15 is disposed between the photoelectric conversion element 101 and another photoelectric conversion element 101 that is adjacent to the photoelectric conversion element 101 in the arrow X direction and the arrow Y direction. The pixel isolation region 14 and the element isolation region 15 both optically and electrically isolate the adjacent pixels 100 and the adjacent photoelectric conversion elements 101.

As illustrated in FIG. 3, here, the one pixel 100 is built by a total of the four photoelectric conversion elements 101: the two photoelectric conversion elements 101 arrayed in the arrow X direction and the two photoelectric conversion elements 101 arrayed in the arrow Y direction.

As illustrated in FIG. 2, the first wiring line layer 12 includes, for example, a wiring line 121 that constructs a multilayer wiring line structure, an insulator as an inter-layer insulating film with no reference numeral, or the like. In addition, in the first wiring line layer 12 is disposed a portion of a feed-through wiring line that penetrates from the first wiring line layer 12 to the second base body 20. The feed-through wiring line is formed as the floating diffusion 104, for example. The feed-through wiring line is formed of, for example, a wiring line material including tungsten (W).

The second base body 20 includes a second semiconductor layer 21 and a second wiring line layer 22 disposed on opposite side to side of the first base body 10 of the second semiconductor layer 21. The second semiconductor layer 21 is formed of monocrystalline silicon.

As illustrated in FIG. 2 and FIG. 4, the second semiconductor layer 21 includes the pixel circuit 200 and the variable capacitance circuit 300. That is, the second semiconductor layer 21 includes a reset transistor 201, an amplification transistor 202, and a selection transistor 203 of the pixel circuit 200 (See FIG. 1). Here, the amplification transistor 202 may be denoted as “AMP”. The second semiconductor layer 21 further includes the switch 301, the variable capacitor 302, and the capacitor 303 of the variable capacitance circuit 300.

The pixel circuit 200 is disposed on a principal surface portion on the opposite side to the side of the first base body 10 of the second semiconductor layer 21. Here, the principal surface portion is used to mean a main surface region that forms transistors, capacitors, resistors, or the like.

As illustrated in FIG. 2 and FIG. 4, the reset transistor 201 is disposed on a principal surface portion of the semiconductor region 212, within the semiconductor region 212 surrounded by the element isolation region 211 and electrically isolated from other regions of the second semiconductor layer 21. Although a structure is not specifically limited, here, a trench isolation structure is adopted in the element isolation region 211, which improves a degree of integration. In addition, the semiconductor region 212 is formed as a p-type well region.

The reset transistor 201 includes the n-channel conductivity type IGFET. The reset transistor 201 includes a channel forming region 213, a gate insulating film 214, a gate electrode (control electrode) 215, and a pair of main electrodes (terminals) 216. The pair of main electrodes 216 is the source region and the drain region and formed by the n-type semiconductor region. The channel forming region 213 is formed on the principal surface portion of the semiconductor region 212 between the pair of main electrodes 216. The gate insulating film 214 is disposed along the channel forming region 213, and formed of, for example, a silicon oxide (SiO) film, a silicon nitride (SiN) film, or a stacked film of the silicon oxide (SiO) film and the silicon nitride (SiN) film. The gate electrode 215 is disposed along the gate insulating film 214 and formed of polycrystalline silicon, for example.

The selection transistor 203 is disposed on the principal surface portion of the semiconductor region 212, within the semiconductor region 212 that is surrounded by the element isolation region 211 and electrically isolated from the other regions. Similarly to the reset transistor 201, the selection transistor 203 includes the n-channel conductivity type IGFET. In addition, the selection transistor 203 includes the channel forming region 213, the gate insulating film 214, the gate electrode (control electrode) 215, and the pair of main electrodes (terminals) 216.

The amplification transistor 202 is disposed on the principal surface portion of the semiconductor region 212, within the semiconductor region 212 that is surrounded by the element isolation region 211 and electrically isolated from the other regions. Similarly to the reset transistor 201, the amplification transistor 202 includes the n-channel conductivity type IGFET. In addition, the amplification transistor 202 includes the channel forming region 213, the gate insulating film 214, the gate electrode (control electrode) 215, and the pair of main electrodes (terminals) 216.

Here, the amplification transistor 202 includes a fin (Fin) type structure. The fin type structure is a structure in which both ends of the gate electrode 215 in a gate width direction are extended from the principal surface of the semiconductor region 212 to a depth direction to expand the gate width dimension in the depth direction. Adoption of the fin type structure makes it possible to increase an amount of electric current of the amplification transistor 202 in the conductive state.

As illustrated in FIG. 4, the reset transistor 201, the selection transistor 203, and the amplification transistor 202 of the pixel circuit 200 are disposed in the region of this one pixel 100, corresponding to the one pixel 100 when viewed in the arrow Y direction (hereinafter simply referred to as “in a planar view”).

### (4) Specific Configuration of Variable Capacitance Circuit 300

As illustrated in FIG. 2 and FIG. 4, the switch 301 of the variable capacitance circuit 300 is configured by an identical structure to the reset transistor 201, or the like. That is, the switch 301 is disposed on the principal surface portion of the semiconductor region 212, within the semiconductor region 212 that is surrounded by the element isolation region 211 and electrically isolated from the other regions of the second semiconductor layer 21. The switch 301 includes the channel forming region 213, the gate insulating film 214, the gate electrode (first control electrode), and the pair of main electrodes (first main electrode and second main electrode) 216.

In the first embodiment, the variable capacitor 302 of the variable capacitance circuit 300 is configured utilizing a p-channel conductivity type IGFET. That is, the variable capacitor 302 is disposed on a principal surface portion of a semiconductor region 217, within the semiconductor region 217 that is surrounded by the element isolation region 211 and electrically isolated from the other regions of the second semiconductor layer 21. The semiconductor region 217 is formed as an n-type well region. The variable capacitor 302 includes the semiconductor region (first semiconductor region) 217, a channel forming region 218, the gate insulating film 214, the gate electrode (second control electrode) 215, and a pair of main electrodes (third main electrode and fourth main electrode) 219. The main electrodes 219 are formed of the p-type semiconductor regions.

That is, the variable capacitor 302 is such configured that the semiconductor region 217 is the first electrode and the gate electrode 215 is the second electrode, the gate electrode 215 being formed, with the gate insulating film 214 interposed as an insulator in between, in the semiconductor region 217. Furthermore, in the variable capacitor 302, the pair of main electrodes 219 is electrically short-circuited.

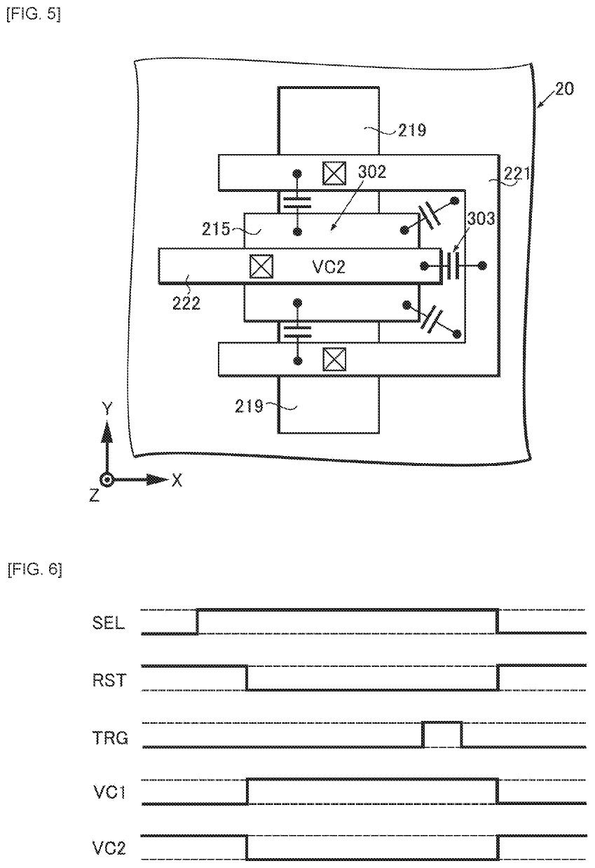

As illustrated in FIG. 4 and FIG. 5, in a planar view, in the variable capacitor 302, the gate electrode 215 is formed like a rectangle. Then, a wiring line (first wiring line) 221 is extended along a periphery of three side surfaces of the gate electrode 215, the wiring line 221 short-circuiting between the pair of main electrodes 219. In addition, in the variable capacitor 302 is disposed a wiring line (second wiring line) 222 facing the gate electrode 215 and electrically coupled to the gate electrode 215. The wiring line 221 and the wiring line 222 lying in a higher layer than the gate electrode 215 are formed in the second wiring line layer 22.

That is, the variable capacitor 302 has a layout that the wiring line 222 having an I-shape in a planar view penetrates into a middle portion of the wiring line 221 having a U-shape in a planar view. Therefore, a value of parasitic capacitance to be added between the wiring line 221 and the wiring line 222 is increased, by increasing an area where the wiring line 221 is opposed to the wiring line 222. This parasitic capacitor configures the capacitor 303 of the variable capacitance circuit 300.

As illustrated in FIG. 4, in a planar view, the switch 301, the variable capacitor 302, and the capacitor 303 of the variable capacitance circuit 300 are disposed in the region of this pixel 100, together with the pixel circuit 200, and corresponding to the one pixel 100.

As illustrated in FIG. 2, the second wiring line layer 22 includes the wiring line the wiring line 221 that constructs the multilayer wiring line structure, the wiring line 222, and an insulator as an unillustrated inter-layer insulating film, or the like.

It is to be noted that the solid-state imaging device 1 according to the first embodiment may further include a third base body on the side opposite to the side of the first base body 10 of the second base body 20. On the third base body, it is possible to dispose, for example, a control circuit that controls the pixel circuit 200; a logic circuit including a processing circuit that processes an electric signal read out from the pixel circuit 200; or a memory circuit that stores information, or the like.

### [Operations of Pixel Circuit 200 and Variable Capacitance Circuit 300 of Solid-State Imaging Device 1]

FIG. 6 illustrates an example of operations of the pixel circuit 200 and the variable capacitance circuit 300 of the solid-state imaging device 1. A horizontal axis represents time and a vertical axis represents each signal.

First, in the pixel circuit 200, in a case where a high-level selection signal SEL is inputted to the control terminal of the selection transistor 203, the selection transistor 203 is controlled to be in the conductive state. Subsequently, a low-level reset signal RST is inputted to the control terminal of the reset transistor 201, and the reset transistor 201 is controlled to be in the non-conductive state.

Thereafter, in a case a transfer signal TRG is inputted to the control terminal of the transfer transistor 102, the electric charge generated through photoelectric conversion of the photoelectric conversion element 101 is inputted to the control terminal of the amplification transistor 202 through the floating diffusion 104. In the amplification transistor 202, an electric signal is generated with a gain corresponding to the electric charge amount (number of electrons) of the electric charges to be transferred through the floating diffusion 104.

Here, in the variable capacitance circuit 300, in accordance with timing of the reset signal RST, the first control signal VC1 is inputted to the control terminal of the switch 301 and the second control signal VC2 is inputted to the second electrode of the variable capacitor 302.

In FIG. 6, by way of example, the high-level first control signal VC1 is inputted to the control terminal of the switch 301 and the low-level second control signal VC2 is inputted to the second electrode of the variable capacitor 302. At this time, the switch 301 is controlled to be in the conductive state, and a capacitance value generated by the variable capacitor 302 is controlled to be “large”.

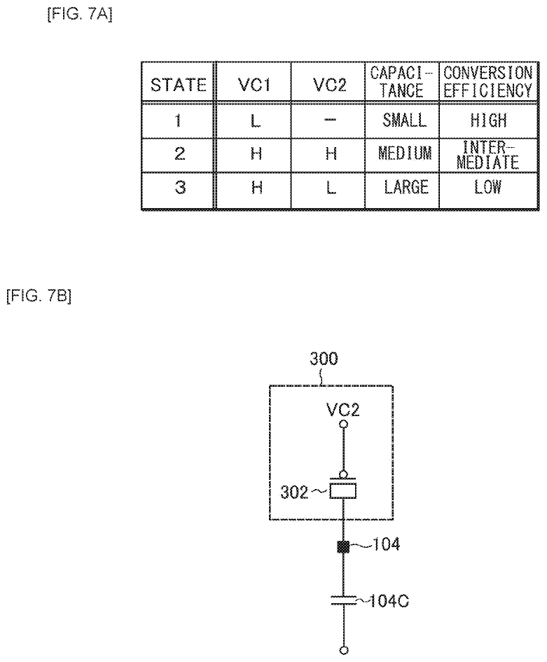

FIG. 7A illustrates a table that describes the conversion efficiency corresponding to a readout operation of the solid-state imaging device 1. For example, in the one pixel 100, when the amount of the electric charges generated by the plurality of photoelectric conversion elements 101 is small and the electric charge amount of the electric charges to be transferred to the floating diffusion 104 is “small”, the first control signal VC1 is at the low-level, and the switch 301 is controlled to be in the non-conductive state.

The amount of the electric charges generated includes both of a case where in the one pixel 100, a total amount of the electric charges generated by the plurality of photoelectric conversion elements 101 is small, and a case where the amount of the electric charges generated by causing only specific photoelectric conversion elements 101 of the plurality of photoelectric conversion elements 101 to operate is small.

At this time, the second control signal VC2 is considered to be in a floating state. This makes the capacitance value of the variable capacitor 302 “small”, which makes it possible to control the conversion efficiency in the amplification transistor 202 to be “high” (state 1).

In addition, when the electric charge amount of the electric charges to be transferred to the floating diffusion 104 is “medium”, the first control signal VC1 is at a high-level, and the switch 301 is controlled to be in the conductive state. At this time, the second control signal VC2 is at the high-level. This makes the capacitance value of the variable capacitor 302 “medium”, which makes it possible to control the conversion efficiency in the amplification transistor 202 to be “intermediate” (state 2).

Then, when the electric charge amount of the electric charges to be transferred to the floating diffusion 104 is “large”, the first control signal VC1 is at the high-level, and the switch 301 is controlled to be in the conductive state. At this time, the second control signal VC2 is at the low-level. This makes the capacitance value of the variable capacitor 302 “large”, which makes it possible to control the conversion efficiency in the amplification transistor 202 to be “low” (state 3).

FIG. 7B illustrates a schematic circuit configuration of the variable capacitance circuit 300. In the first embodiment, the variable capacitor 302 is configured utilizing the p-channel conductivity type IGFET. In a case where the electric charge amount (number of electrons) to be transferred to the floating diffusion 104 increases, potential of the floating diffusion 104 decreases. In response to this, the capacitance value of the parasitic capacitor 104C to be added to the floating diffusion 104 increases.

However, because the variable capacitor 302 is configured utilizing the p-channel conductivity type IGFET, reversely, the capacitance value decreases. That is, the capacitance value of the variable capacitor 302 fluctuates in a direction to compensate for capacitance fluctuation in the parasitic capacitor 104C caused by a potential fluctuation of the floating diffusion 104.

### WORKINGS/EFFECTS

As illustrated in FIG. 1 to FIG. 5, the solid-state imaging device 1 according to the first embodiment includes the photoelectric conversion elements 101, the transfer transistors 102, the pixel 100 in which the plurality of photoelectric conversion elements 101 and transfer transistors 102 is arrayed, the floating diffusions 104, the pixel circuit 200, and the variable capacitance circuits 300.

The photoelectric conversion element 101 generates electric charge from light through photoelectric conversion. The transfer transistor 102 is coupled to the photoelectric conversion element 101. The floating diffusion 104 is commonly coupled, with the respective transfer transistors 102 interposed in between, to the plurality of photoelectric conversion elements 101 of the pixel 100, and transfers the electric charge. The pixel circuit 200 is coupled to the floating diffusion 104 and converts the electric charges into electric signals.

Here, the variable capacitance circuit 300 includes at least the switch 301 and the variable capacitor 302. The one main electrode (first main electrode) 216 of the switch 301 is coupled to the floating diffusion 104. The first control signal VC1 is inputted to the gate electrode (first control electrode) 215, the first control signal VC1 controlling the conductive state and the non-conductive state in accordance with the electric charge amount of the floating diffusion 104. The first electrode of the variable capacitor 302 is coupled to the other main electrode (second main electrode) 216 of the switch 301. The second control signal VC2 is inputted to the second electrode, the second control signal VC2 controlling the capacitance value in accordance with the electric charge amount.

In the variable capacitance circuit 300, it is possible to change the capacitance value to a large number of values, such as three or more values, by controlling the conductive state and the non-conductive state of the switch 301 with the first control signal VC1 and controlling the capacitance value of the variable capacitor 302 with the second control signal VC2. As a result, it is possible to obtain the sufficient variable amount of the capacitance value, which thus allows for expansion of the variable range of the conversion efficiency.

In addition, as illustrated in FIG. 7A, in the solid-state imaging device 1, the switch 301 of the variable capacitance circuit 300 is controlled to be in the non-conductive state when the electric charge amount of the floating diffusion 104 is “small”, and controlled to be in the conductive state when the electric charge amount is “medium” or “large”. The variable capacitor 302 controls the capacitance value to be “small” when the electric charge amount is “small”, controls the capacitance value to be “medium” when the electric charge amount is “medium”, and controls the capacitance value to be “large” when the amount of electric charges is “large”.

As a result, it is possible to expand the variable range of the conversion efficiency because the variable capacitance circuit 300 is able to control the conversion efficiency to three values of “high”, “medium”, and “low”.

Furthermore, as illustrated in FIG. 1, FIG. 2, and FIG. 4, in the solid-state imaging device 1, the switch 301 of the variable capacitance circuit 300 is the n-channel conductivity type IGFET. On the other hand, the variable capacitor 302 of the variable capacitance circuit 300 includes the MIS type variable capacitance diode structure. Therefore, it is possible to easily realize the variable capacitance circuit 300 that allows for the expansion of the variable range of the conversion efficiency.

In addition, as illustrated in FIG. 2, FIG. 4, FIG. 5, and FIG. 7B, in the solid-state imaging device 1, the variable capacitor 302 of the variable capacitance circuit 300 includes the p-channel conductivity type IGFET. That is, the variable capacitor 302 has such a configuration that the semiconductor region (first semiconductor region) 217 electrically isolated from the other regions is the first electrode and the gate electrode (second control electrode) is the second electrode, the gate electrode being formed, with the gate insulating film (insulator) 214 interposed in between, in the semiconductor region 217. The pair of main electrodes (third main electrode and fourth main electrode) 219 is short-circuited.

Therefore, the capacitance value of the variable capacitor 302 fluctuates in the direction to compensate for the capacitance fluctuation in the parasitic capacitor 104C caused by the potential fluctuation in the floating diffusion 104. Hence, the variable capacitance circuit 300 is able to maintain the linearity of the conversion efficiency.

Furthermore, as illustrated in FIG. 1, in the solid-state imaging device 1, the variable capacitor 302 of the variable capacitance circuit 300 further includes the capacitor 303 that is electrically coupled in parallel between the first electrode and the second electrode. The capacitor 303 makes it possible to expand an amount of change in the variable capacitor 302.

In addition, as illustrated in FIG. 1 and FIG. 5, in the solid-state imaging device 1, the variable capacitor 302 of the variable capacitance circuit 300 includes the p-channel conductivity type IGFET. Then, the wiring line (first wiring line) 221 and the wiring line (second wiring line) 222 are disposed. The wiring line 221 is extended along the periphery of the side surfaces of the gate electrode (second control electrode) 215, and short-circuits between the pair of main electrodes 219 (third main electrode and fourth main electrode). The wiring line 222 faces the gate electrode 215 and is electrically coupled to the gate electrode 215, and inputs the second control signal VC2.

This makes it possible to increase the capacitance value of the parasitic capacitor that constructs the capacitor 303, thereby being able to further expand the amount of change in the capacitance value of the variable capacitor 302.

### First Modification Example

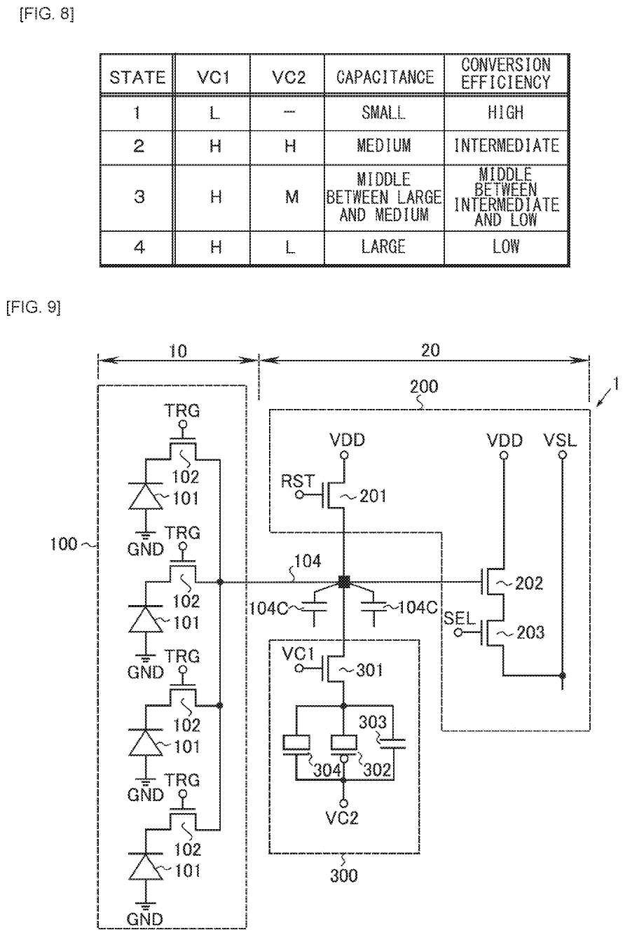

Next, a description will be given of a solid-state imaging device 1 according to the first modification example of the first embodiment with reference to FIG. 8. It is to be noted that in the first modification example and modification examples to be described hereinafter, or in the second embodiment and the embodiments to be described hereinafter, same or subsequently same components as the components of the solid-state imaging device 1 according to the first embodiment will be denoted by same reference numerals, and that an overlapping description will be omitted.

FIG. 8 illustrates a table describing the conversion efficiency corresponding to a readout operation of the solid-state imaging device 1 according to the first modification example. In this description, reference is made to the circuit diagram illustrated in FIG. 1.

In the one pixel 100, when the amount of electric charges generated by the plurality of photoelectric conversion elements 101 is small and the electric charge amount of the electric charges to be transferred to the floating diffusion 104 is “small”, the first control signal VC1 is at low-level, and the switch 301 is controlled to be in the non-conductive state.

At this time, the second control signal VC2 is in the floating state. As a result, the capacitance value of the variable capacitor 302 is “small”. The capacitance value to be added to the floating diffusion 104 is only the capacitance value of the parasitic capacitor 104C because the switch 301 is in the non-conductive state. The capacitance value of the parasitic capacitor 104C is 2f, for example. This makes it possible to control the conversion efficiency in the amplification transistor 202 to be “high” (State 1).

In addition, when the electric charge amount of the electric charges to be transferred to the floating diffusion 104 is “medium”, the first control signal VC1 is at high-level, and the switch 301 is controlled to be in the conductive state. At this time, the second control signal VC2 is at high-level. Because the switch 301 is in the conductive state, the capacitance value to be added to the floating diffusion 104 is a capacitance value obtained by adding the capacitance value of the capacitor 303 of the variable capacitance circuit 300 to the capacitance value of the parasitic capacitor 104C. This added capacitance value is 3f, for example. As a result, the capacitance value to be generated by the variable capacitance circuit 300 is “medium”, which makes it possible to control the conversion efficiency in the amplification transistor 202 to be “medium” (State 2).

In addition, when the electric charge amount of the electric charges to be transferred to the floating diffusion 104 is “large”, the first control signal VC1 is at high-level, and the switch 301 is controlled to be in the conductive state. At this time, the second control signal VC2 is at low-level. Because the switch 301 is in the conductive state, the capacitance value to be added to the floating diffusion 104 is a capacitance value obtained by adding the capacitance values of the variable capacitor 302 and the capacitor 303 of the variable capacitance circuit 300 to the capacitance value of the parasitic capacitor 104C. This added capacitance value is 4f, for example. As a result, the capacitance value of the variable capacitance circuit 300 is “large”, which makes it possible to control the conversion efficiency in the amplification transistor 202 to be “low” (State 4).

In addition, when the electric charge amount of the electric charges to be transferred to the floating diffusion 104 is in the “middle” between “large” and “medium”, the first control signal VC1 is at high-level, and the switch 301 is controlled to be in the conductive state. At this time, the second control signal VC2 is at intermediate level between the high-level and the low-level. Because the switch 301 is in the conductive state, the capacitance value to be added to the floating diffusion 104 is a capacitance value obtained by adding the capacitance values of the variable capacitor 302 and the capacitor 303 of the variable capacitance circuit 300 to the capacitance value of the parasitic capacitor 104C. This added capacitance value is 3.5f, for example. As a result, the capacitance value of the variable capacitance circuit 300 is in the “middle” between “large” and “medium”, which makes it possible to control the conversion efficiency in the amplification transistor 202 to be in the “middle” between “low” and “intermediate” (State 3).

As illustrated in FIG. 8, in the solid-state imaging device 1 according to the first modification example, the variable capacitor 302 of the variable capacitance circuit 300 controls the capacitance value to be in the “middle” between “medium” and “large”, when the electric charge amount of the floating diffusion 104 is in the “middle” between “medium” and “large”.

As a result, the variable capacitance circuit 300 is able to control the conversion efficiency to four values of “large”, “medium”, “middle”, and “small”, which thus makes it possible to further expand the variable range of the conversion efficiency.

Furthermore, in the variable capacitance circuit 300, in the case of State 1 where no capacitor is added, by setting the first control signal VC1 and the second control signal VC2 to low-level, the parasitic capacitor to be added to each of the wiring line 221 and the wiring line 222 is coupled in series. Therefore, for a case where the first control signal VC1 and the second control signal VC2 are at high-level, the variable capacitance circuit 300 is able to expand the variable range.

### Second Modification Example

In a solid-state imaging device 1 according to the second modification example of the first embodiment, the variable capacitor 302 of the variable capacitance circuit 300 as illustrated in FIG. 1 includes the fin type structure, similarly to the amplification transistor 202 having the fin type structure as illustrated in FIG. 2.

In the solid-state imaging device 1 configured in this manner, because the variable capacitor 302 adopts the fin type structure, it is possible to increase the capacitance value of the variable capacitor 302, and further expand the variable range of the variable capacitance circuit 300.

### 2. Second Embodiment

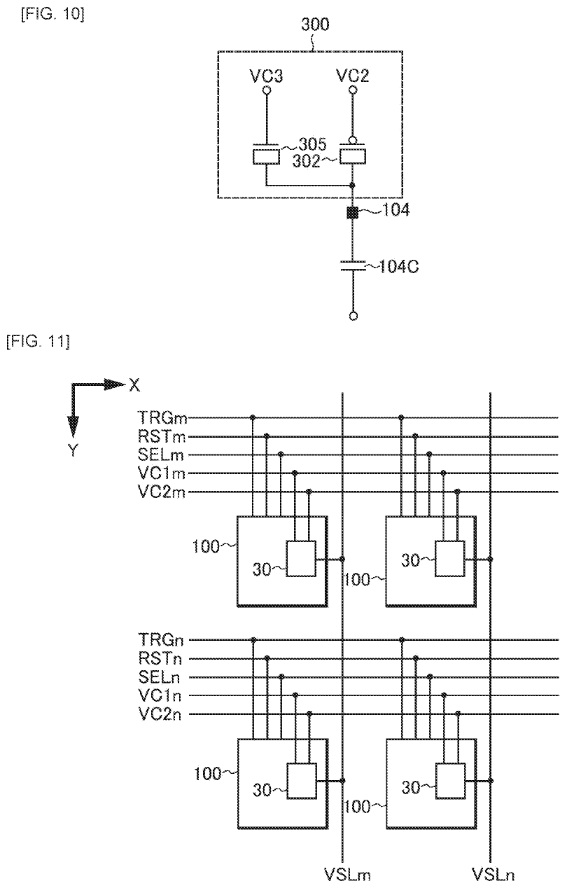

A description of a solid-state imaging device 1 according to the second embodiment of the present disclosure will be given with reference to FIG. 9. FIG. 9 illustrates an example of a circuit configuration of the pixel 100, the pixel circuit 200, and the variable capacitance circuit 300 that construct the solid-state imaging device 1.

The solid-state imaging device 1 according to the second embodiment further includes a variable capacitor 304 in the variable capacitance circuit 300 in the solid-state imaging device 1 according to the first embodiment. The variable capacitor 304 is configured utilizing the n-channel conductivity IGFET (third insulated gate field effect transistor), and is electrically coupled in parallel to the variable capacitor 304. The n-channel conductivity type IGFET is configured by a structure similar to the reset transistor 201 (See FIG. 2), for example. That is, in the n-channel conductivity IGFET, the semiconductor region 212 electrically isolated from the other regions is coupled to the first electrode of the variable capacitor 302, and the gate electrode (third control electrode) 215 is coupled to the second electrode of the variable capacitor 302. The pair of main electrodes (fifth main electrode and sixth main electrode) 216 is short-circuited. This configures the MIS type variable capacitance diode structure.

The solid-state imaging device 1 according to the second embodiment is able to achieve the workings and effects similar to the workings and effects achieved by the solid-state imaging device 1 according to the first embodiment.

Furthermore, as illustrated in FIG. 9, in the solid-state imaging device 1, the variable capacitance circuit further includes the variable capacitor 304. This makes it possible to further expand the variable range of the variable capacitance circuit 300.

### 3. Third Embodiment

A description of a solid-state imaging device 1 according to the third embodiment of the present disclosure will be given with reference to FIG. 10. FIG. 10 illustrates an example of a circuit configuration of the pixel 100, the pixel circuit 200, and the variable capacitance circuit 300 that constructs the solid-state imaging device 1.

In the solid-state imaging device 1 according to the third embodiment, the variable capacitance circuit 300 in the solid-state imaging device 1 according to the first embodiment includes the variable capacitor 302 and a variable capacitor 305. Similarly to the variable capacitor 304 of the solid-state imaging device according to the second embodiment, the variable capacitor 305 is configured utilizing the n-channel conductivity type IGFET (fourth insulated gate field effect transistor), and is electrically coupled in parallel to the variable capacitor 302. That is, in the n-channel conductivity IGFET, the semiconductor region 212 electrically isolated from the other regions is coupled to the first electrode of the variable capacitor 302, and a third control signal VC3 is inputted to the gate electrode (fourth control electrode) 215. The pair of main electrodes (seventh main electrode and eighth main electrode) 216 is short-circuited. This configures the MIS type variable capacitance diode structure. Similarly to the second control signal VC2, the third control signal VC3 controls the capacitance value in accordance with the electric charge amount to be transferred to the floating diffusion 104.

The solid-state imaging device 1 according to the third embodiment is able to achieve the workings and effects similar to the workings and effects achieved by the solid-state imaging device 1 according to the first embodiment.

Furthermore, as illustrated in FIG. 10, in the solid-state imaging device 1, the variable capacitance circuit 300 further includes the variable capacitor 305. This makes it possible to further expand the variable range of the variable capacitance circuit 300.

### 4. Fourth Embodiment

A description of a solid-state imaging device 1 according to the fourth embodiment of the present disclosure will be given with reference to FIG. 11. FIG. 11 illustrates an example of an array configuration of the pixels 100 and the wiring lines of the solid-state imaging device 1.

In the solid-state imaging device 1 according to the fourth embodiment, the plurality of pixels 100 is arrayed in a matrix in each of the arrow X direction and the arrow Y direction. Here, in order to facilitate understanding of the description, the two pixels 100 are arrayed in the arrow X direction, the two pixels 100 are arrayed in the arrow Y direction, and a total of the four pixels is arrayed.

In a first column in the arrow Y direction, a transfer signal wiring line TRGm, a reset signal wiring line RSTm, and a selection signal wiring line SELm are each extended in parallel along the plurality of pixels 100 arrayed in the arrow X direction. The transfer signal wiring line TRGm transfers the transfer signal TRG. The reset signal wiring RSTm transfers the reset signal RST. The selection signal wiring line SELm transfers the selection signal SEL. The transfer signal wiring line TRGm, the reset signal wiring line RSTm, and the selection signal wiring line SELm are each coupled to the plurality of pixels 100 and configured as signal wiring lines shared by the plurality of the pixels 100.

Furthermore, a first control signal wiring line (221) VC1m and a second control signal wiring line (222) VC2m are extended in parallel to each of the transfer signal wiring line TRGm, the reset signal wiring line RSTm, and the selection signal wiring line SELm. Each of the first control signal wiring line (221) VCm and the second control signal wiring line (222) VC2m is coupled to each of the pixels 100 via a pixel selection circuit 30.

In a second column in the arrow Y direction, a transfer signal wiring line TRGn, a reset signal wiring line RSTn, and a selection signal wiring line SELn are each extended in parallel along the plurality of pixels 100 arrayed in the arrow X direction. The transfer signal wiring line TRGn transfers the transfer signal TRG. The reset signal wiring line RSTn transfers the reset signal RST. The selection signal wiring line SELn transfers the selection signal SEL. The transfer signal wiring line TRGn, the reset signal wiring line RSTn, and the selection signal wiring line SELn are each coupled to the plurality of pixels 100 and configured as the signal wiring lines shared by the plurality of the pixels 100.

Furthermore, a first control signal wiring line (221) VC1n and a second control signal wiring line (222) VC2n are extended in parallel to each of the transfer signal wiring line TRGn, the reset signal wiring line RSTn, and the selection signal wiring line SELn. Each of the first control signal wiring line (221) VC1n and the second control signal wiring line (222) VC2n is coupled to each of the pixels 100 via the pixel selection circuit 30.

In a first row in the arrow X direction, a signal selection wiring line VSLm is extended along the plurality of pixels 100 arrayed in the arrow Y direction. The signal selection wiring line VSLm is coupled to each of the pixel selection circuits 30 of each of the plurality of pixels 100 arrayed in the arrow Y direction. The signal selection wiring line VSLm controls each of the pixel selection circuits 30 of each of the plurality of pixels 100 arrayed in the arrow Y direction, and transfers a control signal controlling input to the pixels 100 of the first control signal VC1, the second control signal VC2, or both.

In a second row in the arrow X direction, a signal selection wiring line VSLn is extended along the plurality of pixels 100 arrayed in the arrow Y direction. The signal selection wiring line VSLn is coupled to each of the pixel selection circuits 30 of each of the plurality of pixels 100 arrayed in the arrow Y direction. The signal selection wiring line VSLn controls each of the pixel selection circuits 30 of each of the plurality of pixels 100 arrayed in the arrow Y direction, and transfers the control signal controlling the input to the pixels 100 of the first control signal VC1, the second control signal VC2, or both.

The solid-state imaging device 1 according to the fourth embodiment is able to achieve the workings and effects similar to the workings and effects achieved by the solid-state imaging device 1 according to the first embodiment.

Furthermore, the solid-state imaging device 1 includes the pixel selection circuit 30 in each of the plurality of pixels 100. The pixel selection circuit 30 is controlled by the selection signal to be transferred through the signal selection wiring line VSLm and the signal selection wiring line VSLn. As a result, the plurality of pixels 100 each shares a first control signal wiring line VC1m, a first control signal wiring line VC1n, a second control signal wiring line VC2m, and a second control signal wiring line VC2n, which thus makes it possible to considerably reduce a number of arrays of these signal wiring lines. Therefore, it is possible to improve pixel density of the solid-state imaging device 1.

### 5. Fifth Embodiment

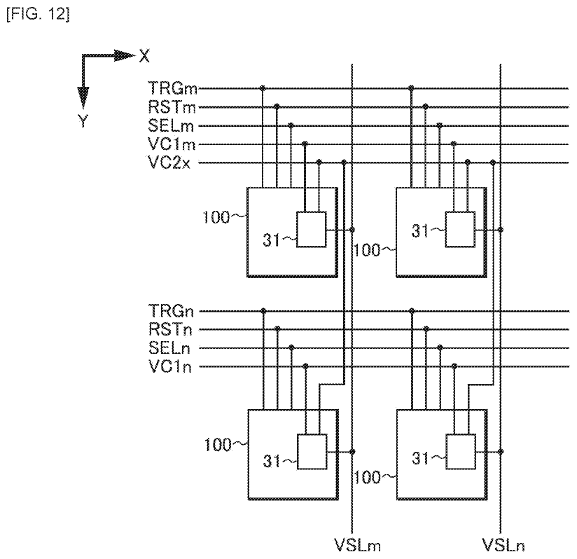

A description of a solid-state imaging device 1 according to the fifth embodiment of the present disclosure will be given with reference to FIG. 12. FIG. 12 illustrates an example of an array configuration of the pixels 1 and the wiring lines of the solid-state imaging device 1.

In the solid-state imaging device 1 according to the fifth embodiment, the plurality of pixels 100 is arrayed in a matrix in each of the arrow X direction and the arrow Y direction.

In the first column in the arrow Y direction, the transfer signal wiring line TRGm, the reset signal wiring line RSTm, and the selection signal wiring line SELm are each extended in parallel along the plurality of pixels 100 arrayed in the arrow X direction. The transfer signal wiring line TRGm, the reset signal wiring line RSTm, and the selection signal wiring line SELm are each coupled to the plurality of pixels 100 and configured as the signal wiring lines shared by the plurality of the pixels 100.

Furthermore, the first control signal wiring line (221) VC1m and a second control signal wiring line (222) VC2x are extended in parallel to each of the transfer signal wiring line TRGm, the reset signal wiring line RSTm, and the selection signal wiring line SELm. Here, the second control signal wiring line VC2x is coupled to each of the pixels 100 via a pixel selection circuit 31.

In the second column in the arrow Y direction, the transfer signal wiring line TRGn, the reset signal wiring line RSTn, and the selection signal wiring line SELn are each extended in parallel along the plurality of pixels 100 arrayed in the arrow X direction. The transfer signal wiring line TRGn, the reset signal wiring line RSTn, and the selection signal wiring line SELn are each coupled to the plurality of pixels 100 and configured as the signal wiring lines shared by the plurality of the pixels 100.

Furthermore, the first control signal wiring line (221) VC1n is extended in parallel to each of the transfer signal wiring line TRGn, the reset signal wiring line RSTn, and the selection signal wiring line SELn. Here, the second control signal wiring line VC2x is coupled to each of the pixels 100 via the pixel selection circuit 31.

In the first row in the arrow X direction, the signal selection wiring line VSLm is extended along the plurality of pixels 100 arrayed in the arrow Y direction. The signal selection wiring line VSLm is coupled to each of the pixel selection circuits 31 of each of the plurality of pixels 100 arrayed in the arrow Y direction. The signal selection wiring line VSLm controls each of the pixel selection circuits 31 of each of the plurality of pixels 100 arrayed in the arrow Y direction, and transfers a control signal controlling input to the pixels 100 of the second control signal VC2.

In the second row in the arrow X direction, the signal selection wiring line VSLn is extended along the plurality of pixels 100 arrayed in the arrow Y direction. The signal selection wiring line VSLn is coupled to each of the pixel selection circuits 31 of each of the plurality of pixels 100 arrayed in the arrow Y direction. The signal selection wiring line VSLn controls each of the pixel selection circuit 31 of each of the plurality of pixels 100 arrayed in the arrow Y direction, and transfers the control signal controlling the input to the pixels 100 of the second control signal VC2.

The solid-state imaging device 1 according to the fifth embodiment is able to achieve the workings and effects similar to the workings and effects achieved by the solid-state imaging device 1 according to the first embodiment.

Furthermore, the solid-state imaging device 1 includes the pixel selection circuit 31 in each of the plurality of pixels 100. The pixel selection circuit 31 is controlled by the selection signal to be transferred through the signal selection wiring line VSLm and the signal selection wiring line VSLn. As a result, the plurality of pixels 100 each shares the second control signal wiring line VC2x, which thus makes it possible to considerably reduce the number of arrays of the second control signal wiring line VC2x. Therefore, it is possible to improve the pixel density of the solid-state imaging device 1.

### 6. Examples of Application to Mobile Bodies

It is possible to apply the technology according to the present disclosure (present technology) to various products. For example, the technology according to the present disclosure may be realized as a device to be mounted on any kind of mobile body such as an automobile, an electric vehicle, a hybrid electric vehicle, a motorcycle, a bicycle, a personal mobility vehicle, an airplane, a drone, a ship, or a robot.

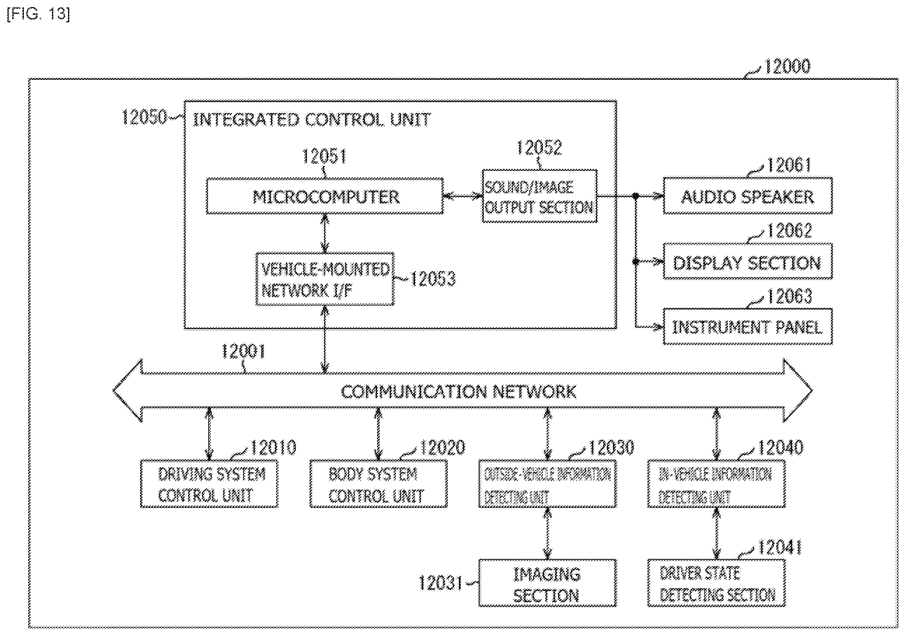

FIG. 13 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 13, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 13, an audio speaker 12061, a display section 12062, and an instrument panel 12063 are illustrated as the output device. The display section 12062 may, for example, include at least one of an on-board display and a head-up display.

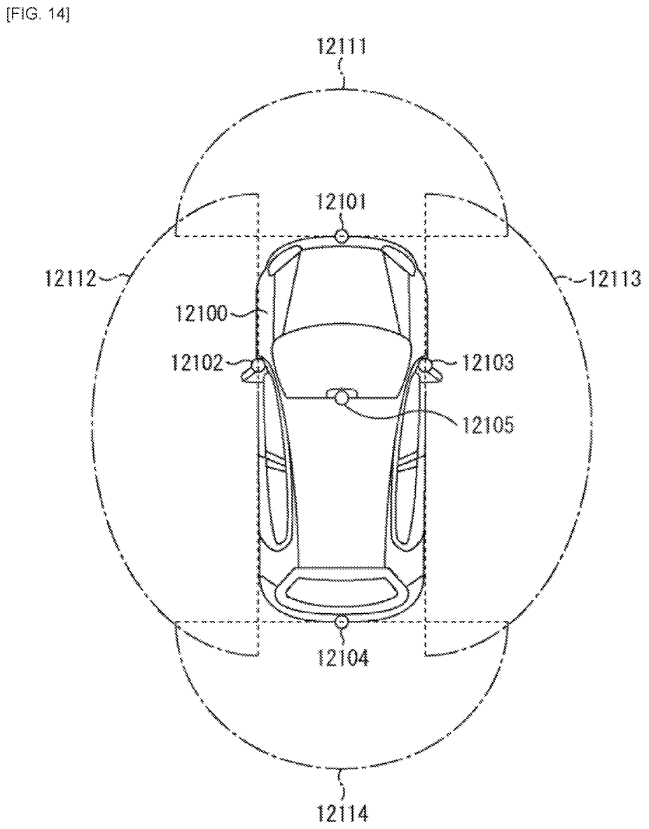

FIG. 14 is a diagram depicting an example of the installation position of the imaging section 12031.

In FIG. 14, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 14 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

As described above, a description has been given of the example of the vehicle control system to which the technology according to the present disclosure may be applied. The technology according to the present disclosure may be applied to the imaging section 12031 of the configurations described above. Application of the technology according to the present disclosure to the imaging section 12031 allows for realization of the imaging section 12031 with a simpler configuration.

### 7. Other Embodiments

The present technology is not limited to the embodiments described above, and various modifications are possible without departing from the gist of the present technology.

For example, of the solid-state imaging devices according to the first embodiment to the fifth embodiment described above, the solid-state imaging devices according to two or more of the embodiments may be combined.

Moreover, it is possible to apply the present technology to a solid-state imaging device in which base bodies having four or more layers are stacked.

In the present disclosure, the solid-state imaging device includes the photoelectric conversion elements, the transfer transistors, the pixel in which the plurality of photoelectric conversion elements and transfer transistors is arrayed, the floating diffusions, the pixel circuit, and the variable capacitance circuits.

The photoelectric conversion element generates electric charge from light through photoelectric conversion. The transfer transistor is coupled to the photoelectric conversion element. The floating diffusion is commonly coupled, with the respective transfer transistors interposed in between, to the plurality of photoelectric conversion elements of the pixel, and transfers the electric charge. The pixel circuit is coupled to the floating diffusion and converts the electric charges into electric signals.

Here, the variable capacitance circuit includes the switch and the variable capacitor. The first main electrode of the switch is coupled to the floating diffusion. The first control signal is inputted to the first control electrode, the first control signal controlling the conductive state and the non-conductive state in accordance with the electric charge amount of the floating diffusion. The first electrode of the variable capacitor is coupled to the second main electrode of the switch. The second control signal is inputted to the second electrode, the second control signal controlling the capacitance value in accordance with the electric charge amount.

In the variable capacitance circuit, it is possible to change the capacitance value to the large number of values, such as three or more values, by controlling the conductive state and the non-conductive state of the switch using the first control signal and controlling the capacitance value using the second control signal. As a result, it is possible to obtain the sufficient variable amount of the capacitance value, which thus allows for expansion of the variable range of the conversion efficiency.

In addition, in the solid-state imaging device, the variable capacitor of the variable capacitance circuit includes the p-channel conductivity type IGFET.

Therefore, the capacitance value of the variable capacitor fluctuates in the direction to compensate for the capacitance fluctuation in the parasitic capacitor caused by the potential fluctuation in the floating diffusion. Hence, the variable capacitance circuit is able to maintain the linearity of the conversion efficiency.

### 8. Configuration of Present Technology

It is to be noted that the present technology may have the following configurations. Inclusion of the present technology makes it possible to provide a solid-state imaging device that is able to change to a large number of capacitance values such as three or more values, and obtain the sufficient variable amount of the capacitance value. Moreover, it is possible to provide a solid-state imaging device that is able to maintain the linearity in the conversion efficiency.

(1)

A solid-state imaging device including:

a photoelectric conversion element that generates electric charge from light through photoelectric conversion;

a transfer transistor that is coupled to the photoelectric conversion element;

a pixel in which a plurality of the photoelectric conversion elements and a plurality of the transfer transistors are arrayed;

a floating diffusion that is commonly coupled, with the respective transfer transistors interposed in between, to the plurality of photoelectric conversion elements of the pixel, and transfers the electric charge;

a pixel circuit that is coupled to the floating diffusion and converts the electric charge into electric signals;

a switch that has a first main electrode coupled to the floating diffusion and has a first control electrode to which a first control signal is inputted, the first control signal controlling a conductive state and a non-conductive state in accordance with an electric charge amount of the floating diffusion; and

a variable capacitor that has a first electrode coupled to a second main electrode of the switch and has a second electrode to which a second control signal is inputted, the second control signal controlling a capacitance value in accordance with the electric charge amount.

(2)

The solid-state imaging device according to (1), in which

the switch is controlled to be in the non-conductive state when the electric charge amount is small, and controlled to be in the conductive state when the electric charge amount is medium or large, and

the variable capacitor controls the capacitance value to be small when the electric charge amount is small, controls the capacitance value to be medium when the electric charge amount is medium, and controls the capacitance value to be large when the electric charge amount is large.

(3)

The solid-state imaging device according to (2), in which

the variable capacitor controls the capacitance value to be in a middle between medium and large when the electric charge amount is in a middle between medium and large.

(4)

The solid-state imaging device according to any one of (1) to (3), in which

the switch includes a first insulated gate field effect transistor of a first conductivity type.

(5)

The solid-state imaging device according to any one of (1) to (4), in which

the variable capacitor includes a variable capacitance diode structure of a metallic body-insulator-semiconductor type in which a semiconductor is the first electrode and a metallic body is the second electrode, the metallic body being formed in the semiconductor with an insulator interposed in between.

(6)

The solid-state imaging device according to any one of (1) to (4), in which

the variable capacitor includes a second insulated gate field effect transistor in which a first semiconductor region is the first electrode, the first semiconductor region being electrically isolated from other regions; a second control electrode is the second electrode, the second control electrode being formed in the first semiconductor region with an insulator interposed in between; and a third main electrode and a fourth main electrode are short-circuited.

(7)

The solid-state imaging device according to (6), in which

the second insulated gate field effect transistor is of a second conductivity type that is opposite to a first conductivity type.

(8)

The solid-state imaging device according to (6) or (7), in which

the second insulated gate field effect transistor is of a p-type.

(9)

The solid-state imaging device according to any one of (1) to (8), further including:

a capacitor electrically coupled in parallel between the first electrode and the second electrode of the variable capacitor.

(10)

The solid-state imaging device according to any one of (6) to (8), in which

the second insulated gate field effect transistor includes a fin type structure in which ends of the second control electrode in a gate width direction are extended to a depth direction of the first semiconductor region.

(11)

The solid-state imaging device according to any one of (6) to (8), further including:

a first wiring line that is extended along a periphery of side surfaces of the second control electrode of the second insulated gate field effect transistor and short-circuits between the third main electrode and the fourth main electrode; and

a second wiring line that faces the second control electrode and is electrically coupled to the second control electrode, and inputs the second control signal to the second electrode.

(12)

The solid-state imaging device according to (9), further including:

a third insulated gate field effect transistor in which a second semiconductor region electrically isolated from other regions is coupled to the first electrode of the variable capacitor; a third control electrode is coupled to the second electrode; and a fifth main electrode and a sixth main electrode are short-circuited.

(13)

The solid-state imaging device according to any one of (1) to (12), further including:

a fourth insulated gate field effect transistor in which a third semiconductor region electrically isolated from other regions is coupled to the first electrode of the variable capacitor; a third control signal is inputted to a fourth control electrode, the third control signal controlling a capacitance value in accordance with the electric charge amount; and a seventh main electrode and an eighth main electrode are short-circuited.

(14)

The solid-state imaging device according to any one of (1) to (13), further including:

a plurality of the pixels arrayed in a predetermined direction;

a first control signal wiring line that is coupled to and shared by the plurality of pixels, and transfers the first control signal;

a second control signal wiring line that is coupled to and shared by the plurality of pixels, and transfers the second control signal; and

a pixel selection circuit that is disposed in each of the plurality of pixels and selects input of the first control signal, the second control signal, or both.

(15)

The solid-state imaging device according to any one of (1) to (14), including:

a first base body in which the pixel is formed; and

a second base body that is stacked on the first base body and in which the pixel circuit is formed, in which

the switch and the variable capacitor are formed in the second base body.

This application claims priority based on Japanese Patent Application No. 2021-145053 filed on Sep. 6, 2021 with Japan Patent Office, the entire contents of which are incorporated in this application by reference.

It should be understood by those skilled in the art that various modifications, combinations, sub-combinations and alterations may occur depending on design requirements and other factors insofar as they are within the scope of the appended claims or the equivalents thereof.

1. A solid-state imaging device comprising:
a photoelectric conversion element that generates electric charge from light through photoelectric conversion;
a transfer transistor that is coupled to the photoelectric conversion element;
a pixel in which a plurality of the photoelectric conversion elements and a plurality of the transfer transistors are arrayed;
a floating diffusion that is commonly coupled, with the respective transfer transistors interposed in between, to the plurality of photoelectric conversion elements of the pixel, and transfers the electric charge;
a pixel circuit that is coupled to the floating diffusion and converts the electric charge into electric signals;
a switch that has a first main electrode coupled to the floating diffusion and has a first control electrode to which a first control signal is inputted, the first control signal controlling a conductive state and a non-conductive state in accordance with an electric charge amount of the floating diffusion; and
a variable capacitor that has a first electrode coupled to a second main electrode of the switch and has a second electrode to which a second control signal is inputted, the second control signal controlling a capacitance value in accordance with the electric charge amount.

2. The solid-state imaging device according to claim 1, wherein
the switch is controlled to be in the non-conductive state when the electric charge amount is small, and controlled to be in the conductive state when the electric charge amount is medium or large, and
the variable capacitor controls the capacitance value to be small when the electric charge amount is small, controls the capacitance value to be medium when the electric charge amount is medium, and controls the capacitance value to be large when the electric charge amount is large.

3. The solid-state imaging device according to claim 2, wherein
the variable capacitor controls the capacitance value to be in a middle between medium and large when the electric charge amount is in a middle between medium and large.

4. The solid-state imaging device according to claim 1, wherein
the switch comprises a first insulated gate field effect transistor of a first conductivity type.

5. The solid-state imaging device according to claim 1, wherein
the variable capacitor includes a variable capacitance diode structure of a metallic body-insulator-semiconductor type in which a semiconductor is the first electrode and a metallic body is the second electrode, the metallic body being formed in the semiconductor with an insulator interposed in between.

6. The solid-state imaging device according to claim 1, wherein
the variable capacitor includes a second insulated gate field effect transistor in which a first semiconductor region is the first electrode, the first semiconductor region being electrically isolated from other regions; a second control electrode is the second electrode, the second control electrode being formed in the first semiconductor region with an insulator interposed in between; and a third main electrode and a fourth main electrode are short-circuited.

7. The solid-state imaging device according to claim 6, wherein
the second insulated gate field effect transistor is of a second conductivity type that is opposite to a first conductivity type.

8. The solid-state imaging device according to claim 6, wherein
the second insulated gate field effect transistor is of a p-type.

9. The solid-state imaging device according to claim 1, further comprising:
a capacitor electrically coupled in parallel between the first electrode and the second electrode of the variable capacitor.

10. The solid-state imaging device according to claim 6, wherein
the second insulated gate field effect transistor includes a fin type structure in which ends of the second control electrode in a gate width direction are extended to a depth direction of the first semiconductor region.

11. The solid-state imaging device according to claim 6, further comprising:
a first wiring line that is extended along a periphery of side surfaces of the second control electrode of the second insulated gate field effect transistor and short-circuits between the third main electrode and the fourth main electrode; and
a second wiring line that faces the second control electrode and is electrically coupled to the second control electrode, and inputs the second control signal to the second electrode.

12. The solid-state imaging device according to claim 9, further comprising:
a third insulated gate field effect transistor in which a second semiconductor region electrically isolated from other regions is coupled to the first electrode of the variable capacitor; a third control electrode is coupled to the second electrode; and a fifth main electrode and a sixth main electrode are short-circuited.

13. The solid-state imaging device according to claim 1, further comprising:
a fourth insulated gate field effect transistor in which a third semiconductor region electrically isolated from other regions is coupled to the first electrode of the variable capacitor; a third control signal is inputted to a fourth control electrode, the third control signal controlling a capacitance value in accordance with the electric charge amount; and a seventh main electrode and an eighth main electrode are short-circuited.

14. The solid-state imaging device according to claim 1, further comprising:
a plurality of the pixels arrayed in a predetermined direction;
a first control signal wiring line that is coupled to and shared by the plurality of pixels, and transfers the first control signal;
a second control signal wiring line that is coupled to and shared by the plurality of pixels, and transfers the second control signal; and
a pixel selection circuit that is disposed in each of the plurality of pixels and selects input of the first control signal, the second control signal, or both.

15. The solid-state imaging device according to claim 1, comprising:
a first base body in which the pixel is formed; and
a second base body that is stacked on the first base body and in which the pixel circuit is formed, wherein
the switch and the variable capacitor are formed in the second base body.
